(19) United States
(12) Patent Application Publication
(10) Pub. No.: US 2013/0119566 A1
(43) Pub. Date: May 16, 2013

(54) Semiconductor Chip and Substrate Transfer/Processing Tunnel -arrangement Extending in a Linear Direction

(71) Applicant: Edward Bok, Lelystad (NL)

(72) Inventor: Edward Bok, Lelystad (NL)

(21) Appl. No.: 13/698,487

(22) PCT Filed: May 18, 2010
(86) PCT No.: PCT/NL2010/000083

§ 371 Date: Jan. 29, 2013

(51) Int. Cl. H01L 21/677

(52) U.S. Cl. CPC H01L 21/677
USPC 257/798; 438/800

(57) ABSTRACT

The invention is related to a semiconductor chip, at-least also accomplished in a semiconductor installation, containing at-least also a long, relatively narrow semiconductor substrate transfer/processing tunnel-arrangement, wherein during its operation at-least also the taking place of successive semiconductor processings of the successive, typically uninterruptedly displacing semiconductor substrate-sections there through and whereby in a device behind its exit by means of dividing these successive semiconductor substrate-sections the accomplishing thereof.

In such semiconductor tunnel-arrangement typically the yearly taking place of the enormous production of approximately 0,4 milliard chips.

Such semiconductor tunnel-arrangement, contained in a semiconductor installation, is not known until yet.

Thereby in addition the already in the accompanying PCT Patent Applications of the Applicant described main advantages of such new semiconductor installation with regard to the existing semiconductor installations, wherein the application of at-least individual semiconductor modules and—chips.

The typically less than 15 meter long semiconductor installation thereby has only a width of typically less than 2 meter on behalf of during its operation therein the accomplishing of such semiconductor chips out of successive semiconductor substrate-sections.

Thereby in such installation the location of at-least also such semiconductor transfer/processing tunnel-arrangement, in this application further described, and wherein during its operation in successive semiconductor processing-sections the uninterruptedly taking place of successive semiconductor processings of the successive semiconductor substrate-sections, uninterruptedly displacing therethrough and such under typically the appliance of an uninterrupted folio or band as an at-least temporary semiconductor underlayer thereof.

In a following favourable execution of this semiconductor installation therein the location of a device on behalf of the storage therein of such a very long folio, that during a very long period of time, typically at-least 0,2 year, an at-least almost uninterruptedly taking place of a linear displacement thereof through such semiconductor tunnel-arrangement.

Furthermore such folio contains parallel upward sidewalls and has a width, that to a small extent is smaller than that of the passage-way of such tunnel-arrangement.

In a favourable execution is such tunnel-arrangement uninterrupted and extends only in a lineair direction.

Thereby in its passage-way only the uninterrupted displacement therethrough of the successive substrate-sections, whereby during the operation of this tunnel it only at the entrance- and exit-side thereof is in an open connections with the atmospheric outer-air under the appliance of a gaseous medium-lock at at-least its entrance.

Further in a favourable execution of this installation behind such tunnel-arrangement the location of a device on behalf of therein at-least by means of dividing the successive, therein uninterruptedly semiconductor processed semiconductor substrate-sections, the accomplishing of such semiconductor chips.

Furthermore contains this installation means on behalf of the government of at-least also the successive semiconductor processings in such tunnel-arrangement and the semiconductor substrate transfer-system on behalf of an at-least almost uninterruptedly uniform displacing therethrough of the successive semiconductor substrate-sections.

For this installation personal on behalf of the taking place of at-least also the following:
a) the start of the operation of such semiconductor tunnel-arrangement and its ending; and
b) supervision of the correct operation of this tunnel-arrangement and its maintenance.

Furthermore contains this installation devices on behalf of the following:
a) the start and end of the continuous supply- and discharge of the semiconductor processing-mediums and the transfer-mediums; and
b) the maintaining of a continuous supply and discharge of these mediums.

The installation typically contains in addition the storage-arrangements for the successive semiconductor processing- and transfer-mediums.

In a favorable alternative execution thereof it contains means on behalf of behind the exit of such tunnel-arrangement the removal of the successive metallic folio/band-sections from the successive semiconductor substrate-sections as a temporary semiconductor underlayer thereof.

Thereby contains this installation in a following favourable execution thereof beyond the exit-side of the tunnel-arrangement means on behalf of displacing such folio toward a storage-roll through a cleaning-device

In a following favourable execution of this installation therein the location of a roll-arrangement at the entrance of the tunnel-arrangement on behalf of the again re-introduce the cleaned folio therein.

Thereby for that purpose behind such underneath this tunnel-arrangement positioned cleaning-device for the metallic folio the location of a device on behalf of the therein upon the top-wall of this folio establishing of a micrometer high layer of fluidic guide-medium to enable an easy displacement thereof through this tunnel-arrangement.

In addition, in another favourable execution of this installation the functioning of such folio as an uninterrupted metallic semiconductor substrate support/transfer-band on behalf of the near the entrance of such tunnel-arrangement applying thereupon of successive typically synthetic folio-sections, thereto derived from a folio storage-roll.

Thereby in a favourable execution of this band its upper-wall at least at the central semiconductor processing-section section thereof is deepened on behalf of the therein insertion of these successive folio-sections and whereby typically a mechanic contact is maintained between its successive band- and folio-sections.

With the existing semiconductor installations under the appliance of storaging of semiconductor wafers in cassettes and a transfer thereof toward and from successive semiconductor processing modules on behalf of the establishing of semiconductor chips, with the already in the other simultaneous filed PCT Patent Applications described many disadvantages thereof.

Furthermore thereby in addition with the application therein of the combination of an almost cylindrical wafer as a semiconductor substrate and successive semiconductor substrate processing-modules, wherein no possible lineair displacement thereof therethrough, thereby on behalf of the accomplishing of a semiconductor substrate, from which by means of a division thereof the obtaining of semiconductor chips, in that way mostly the required establishing of a number of successive semiconductor layers, exclusively positioned in the upward direction above each other, with in-between positioned typical di-electric semiconductor layers, containing metallic semiconductor in-between connections for these layers.

Thereby no possibility of such semiconductor layers to be positionen aside each other in a lineair direction.

In that way the requirement of an extremely expensive and complex semiconductor installation, containing a very large number of semiconductor processing modules.

Thereby, by for instance the application of five upon each other positioned semiconductor layers, with for each thereof typically almost cylindrical layers, the required individual highly complex and expensive semiconductor lightning-devices.

Thereby also for the thereby in-between positioned semi conductor layers also at-least the required appliance of a great number of such semiconductor devices.

In that way, thereby the requirement of a great number of semiconductor cleaning-actions on behalf of the accomplishing of a total semiconductor processing-system for such semiconductor substrate, with thereby a required electric top-layer thereof for the accomplished semiconductor chips.

Thereby also due to the continuously further reduction of the width of the metallic connections in such semiconductor layers, now already typically less than 40 nanometer, an always further hindering the total semiconductor processing-process and such also due to the required extreme exactly above each other positioning of the successive semiconductor layers, with the in-between metallic in-between connections.

In this new semiconductor installation however now also due to these nanometer sized line-widths the possible ideal accomplishing of successive semiconductor substrate-sections, containing typically only one semiconductor layer and from which in a device behind such semiconductor tunnel-arrangement by means of dividing thereof the obtaining of semiconductor chips, containing typically only this single semiconductor layer and still a thereby acceptable circumference thereof. Furthermore, in such semiconductor installation also the possible use and application of the multiple means and methods of the semiconductor devices, which also are described in the related filed Dutch and PCT Patent-Applications.

Furthermore, in this semiconductor installation the possible application of all commonly used semiconductor processings for wafers in semiconductor modules, also such, as already are described in Patents, if therein the mentioning in the text and Claims of the following:
a) an individual semiconductor wafer or—substrate, and/or
b) a whether or not individual semiconductor processing-module,

Further, the in this Patent Application described and shown semiconductor structures, means and methods are also applicable in the semiconductor installations or sections thereof, that are described in the related, by the Applicant applied Patent Applications with regard to in particular such semiconductor tunnel-arrangements.

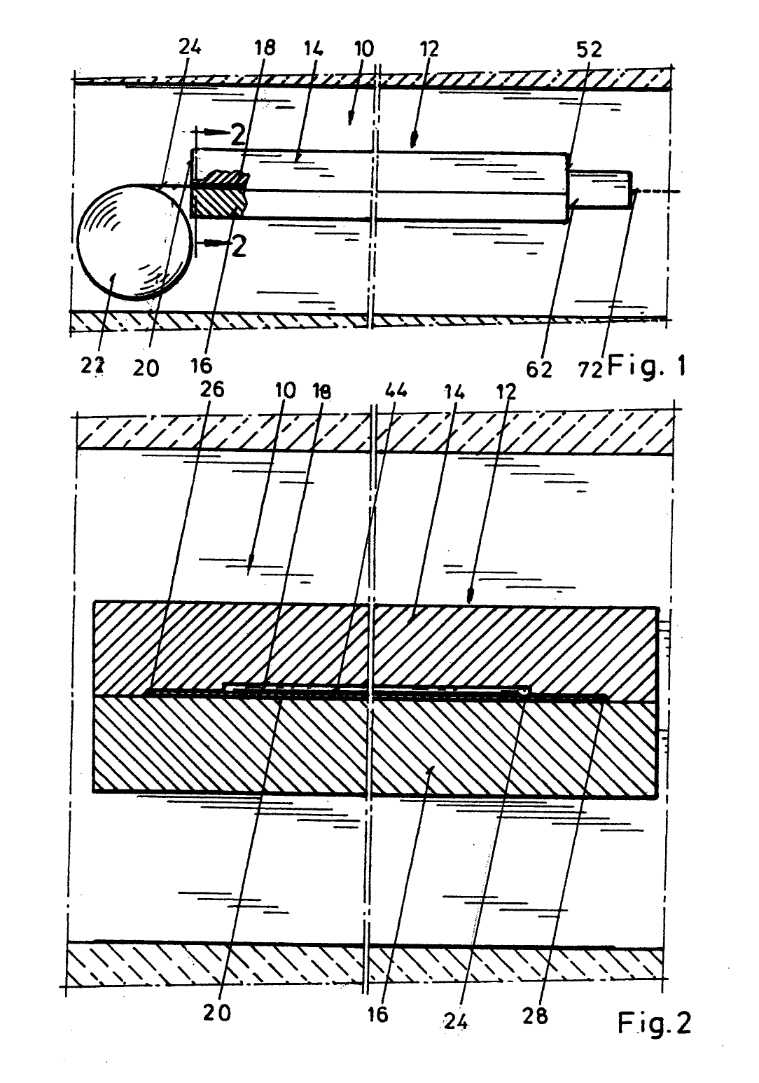

FIG. 1 shows schematically the semiconductor installation according to the invention in a side-view thereof.

FIG. 2 shows the cross-section over the line 2-2 of the in this installation located semiconductor tunnel-arrangement at its entrance-section.

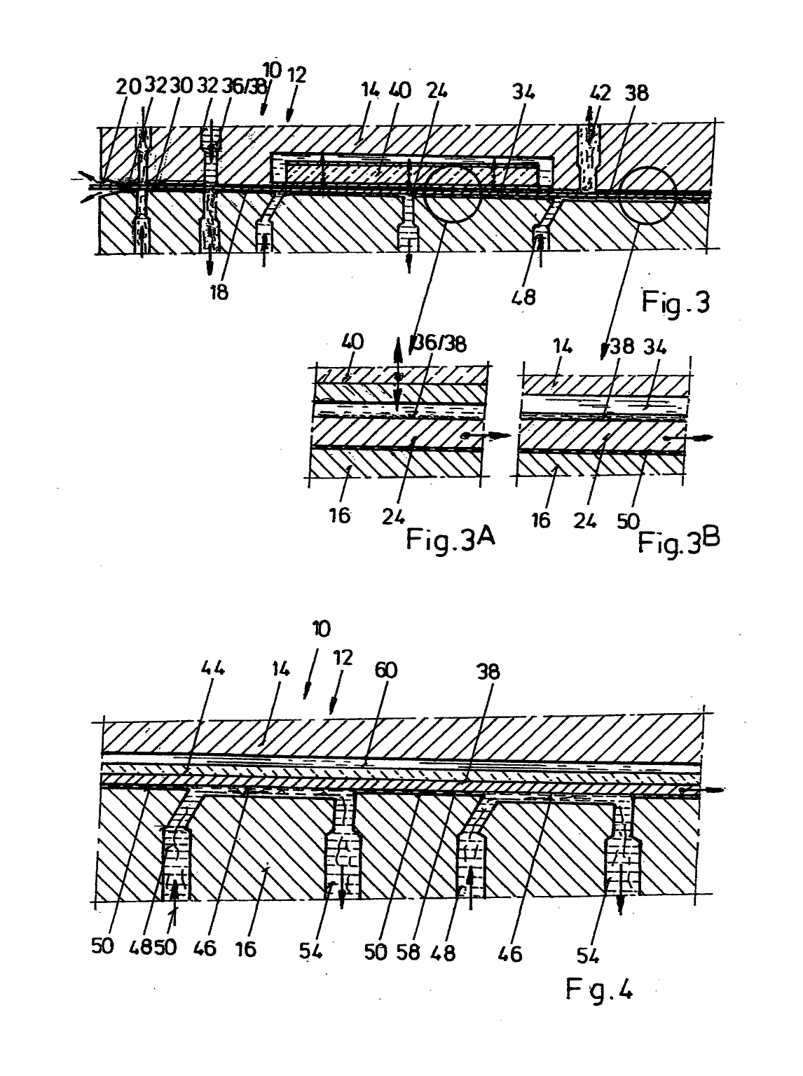

FIG. 3 shows a cross-section in length-direction of the entrance-section of this semiconductor tunnel at its central processing-section.

FIG. 3A shows thereby very enlarged a section of this tunnel-passage at the strip-shaped transducer-arrangement, located in the lowe-section of the uppertunnelblock.

FIG. 3B shows thereby very enlarged the tunnel-passage behind this transducer-arrangement.

FIG. 4 shows very enlarged a cross-section in the length-direction of the tunnel-passage at a supply- and discharge-groove in the lowertunnelblock for fluidic transfer/guidance-medium.

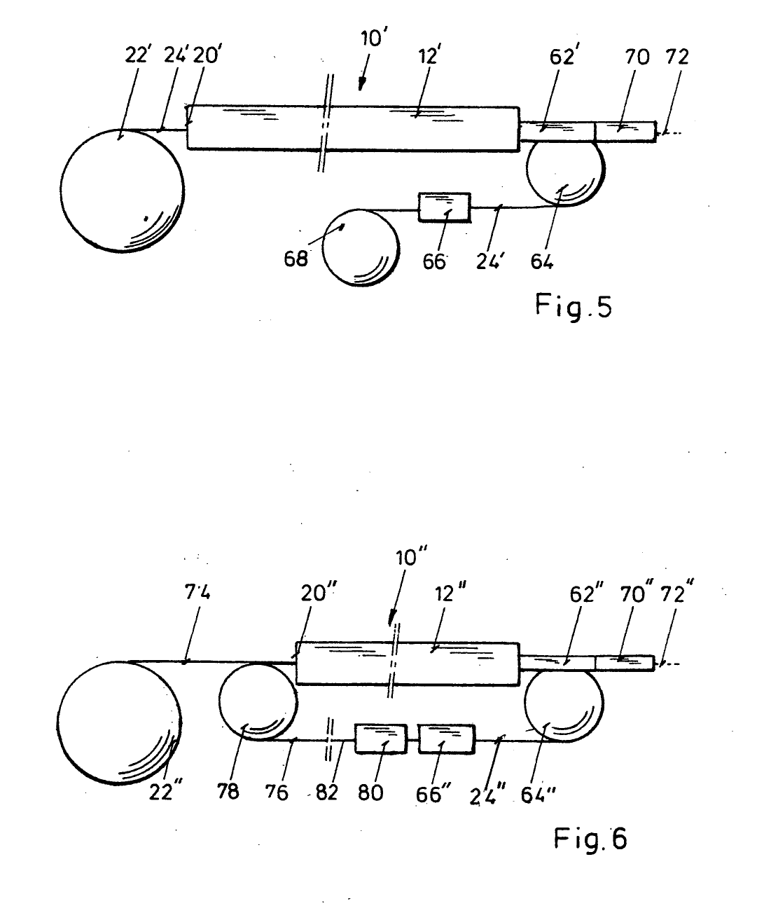

FIG. 5 shows schematically the semiconductor installation in an alternative execution thereof and whereby therein in a device behind the tunnel-arrangement by means of a roll-arrangement the taking place of separation of the successive semiconductor substrate-sections from the successive folio-sections under thereby the storage of the successive folio-sections in a folio storage roll-arrangement.

FIG. 6 shows an alternative execution of the installation according to FIG. 5 and whereby therein at the entrance of the semiconductor tunnel-arrangement the location of a roll-arrangement on behalf of the therewith also accomplishing of an uninterrupted metallic semiconductor support/transfer-band and whereby upon this band typically the applying of successive typically synthetic folio-sections, derived from a folio storage-roll, inserted in this installation.

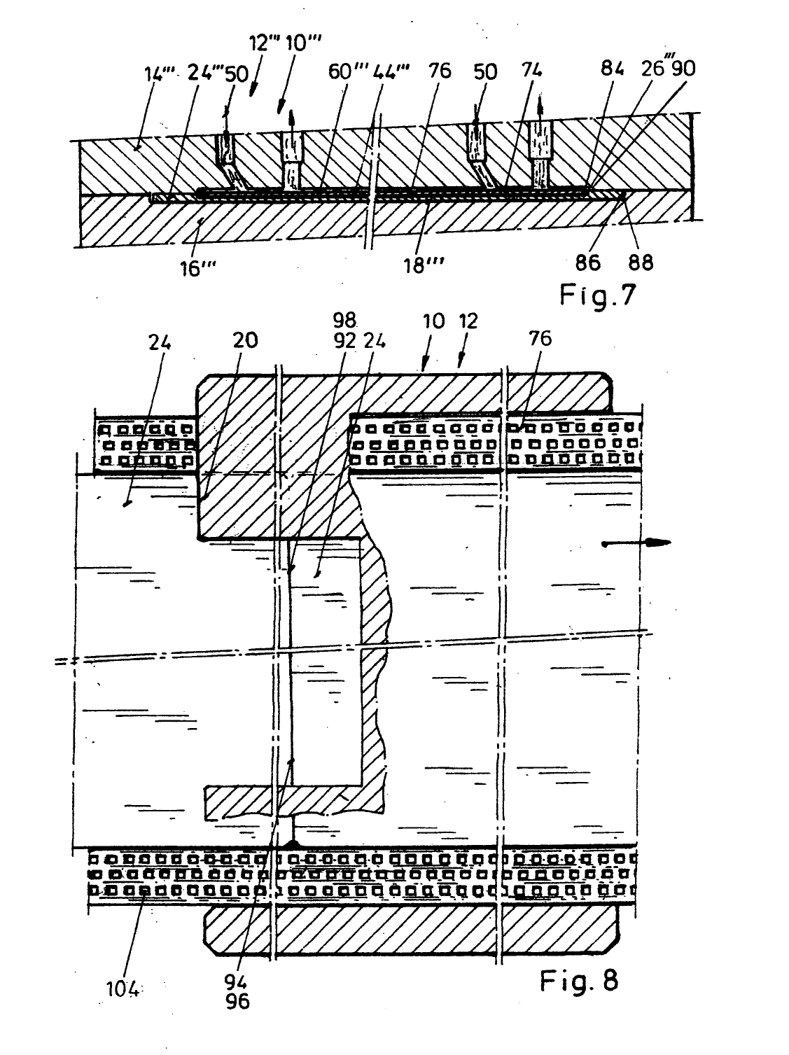

FIG. 7 shows a cross-section of a band-execution, containing a deepened central section of its top-wall on behalf of the therein insertion of successive folio-sections.

FIG. 8 shows a section of an alternative execution of the semiconductor installation, with therein the uninterruptedly displacing through the tunnel-arrangement of the uninterrupted folio support/transfer-band, with thereupon two successive joined-together folios.

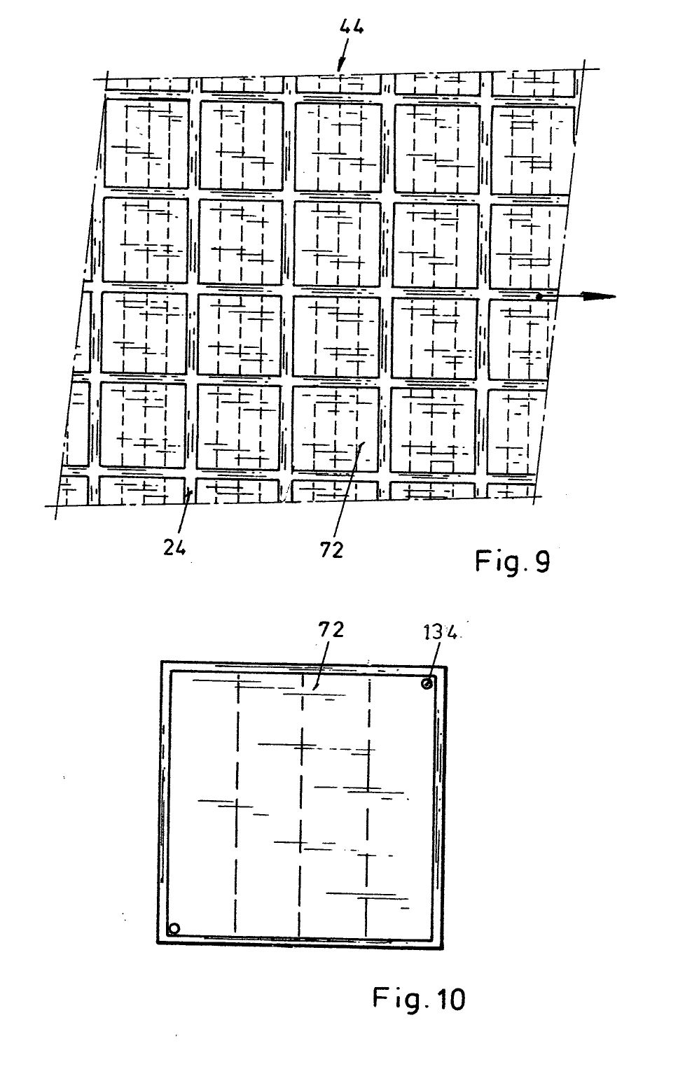

FIG. 9 shows a partial top-view of the successive substrate-sections, displacing through a device behind the exit of the tunnel-arrangement.

FIG. 10 shows very enlarged a top-view of the accomplished semiconductor chip, containing thereby only a single semiconductor top-layer, after a dividing of these successive semiconductor substrate-sections.

FIGS. 11A through F show in this semiconductor tunnel-arrangement after the accomplishing of the successive typically sub-micrometer wide crevices in the di-electric top-layer of the successive semiconductor substrate-sections, displacing through the tunnel-arrangement, thereby the successive phases of the cleaning of these crevices.

FIG. 12 shows thereby for that purpose the appliance of a typically high-frequent vibrating-condition of at-least also these successive semiconductor substrate-sections by means of a rotating notches-shaft, located within the lowertunnelblock.

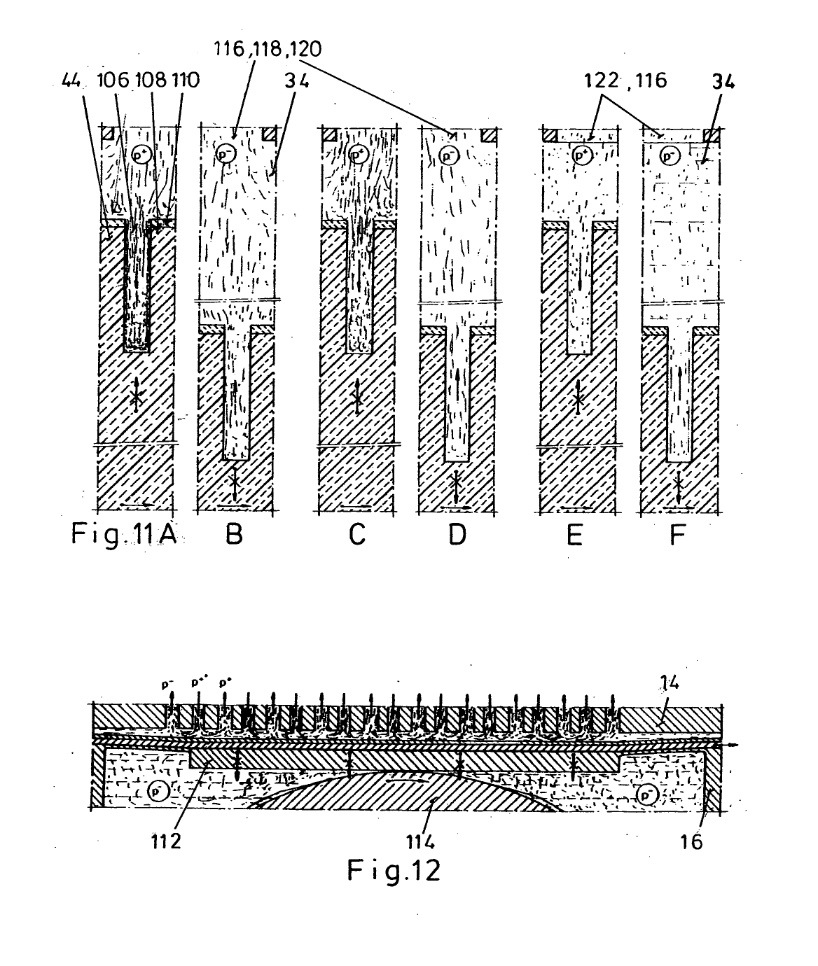

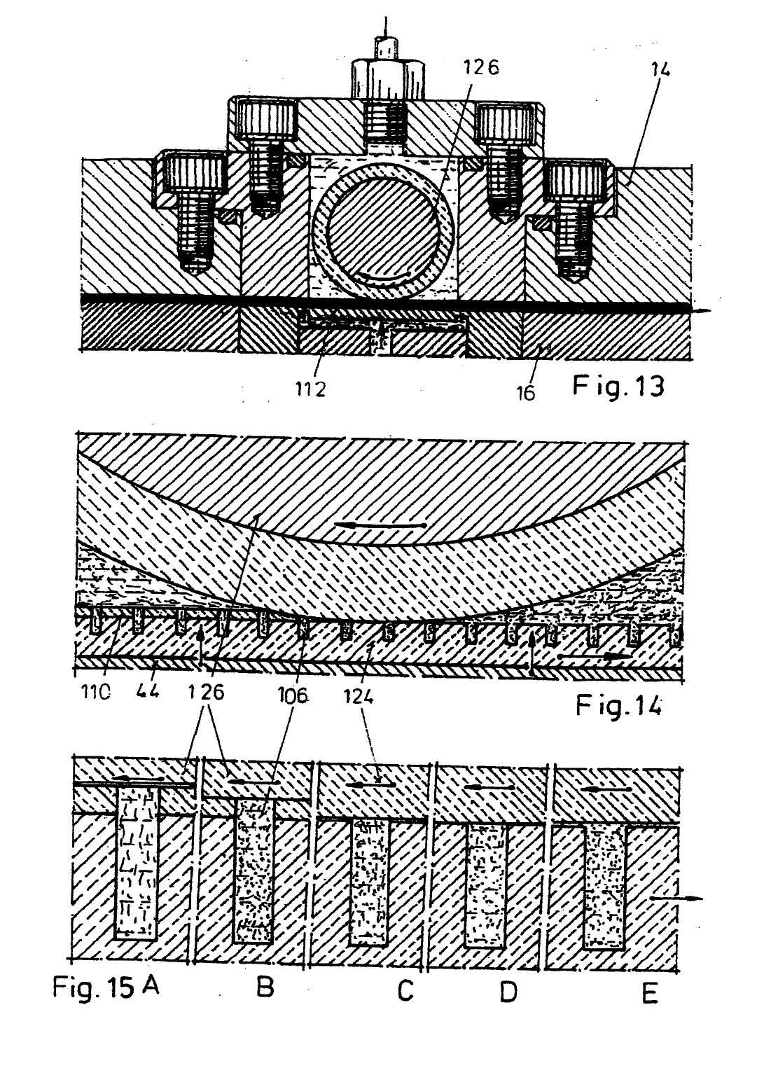

FIG. 13 and very enlarged FIGS. 14 and 15A through E show by means of a rotary grinding-shaft, contained in the uppertunnelblock at its central section, the removal of the remaining part of the required micrometer high solid de-electrical lightning-layer upon the successive semiconductor substrate-sections, displacing underneath.

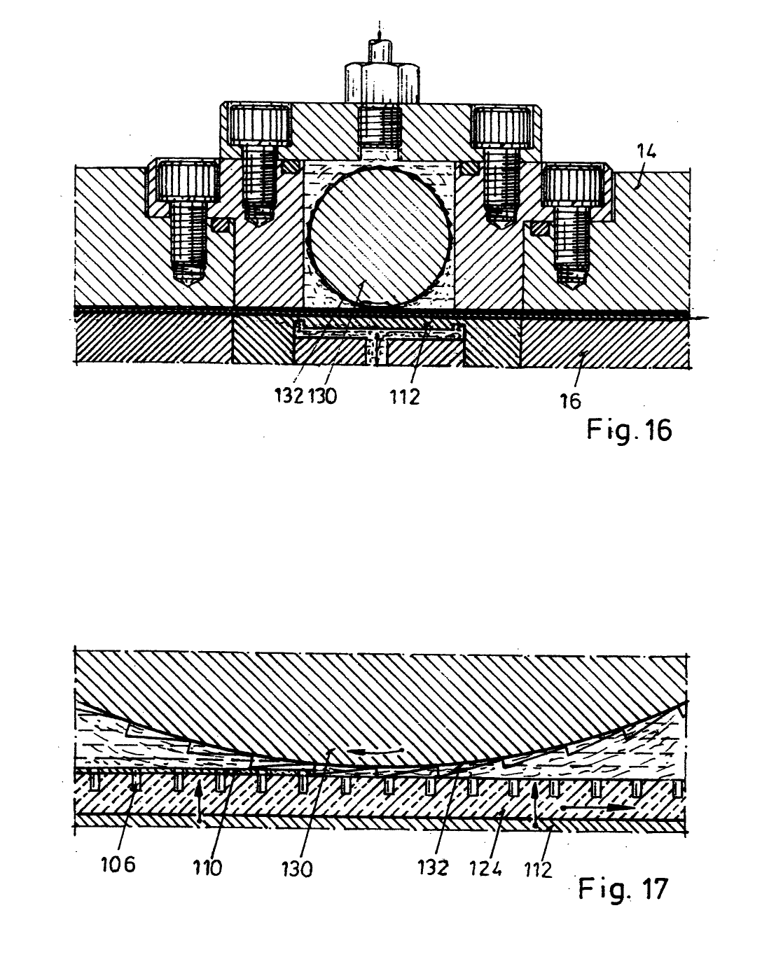

FIG. 16 and very enlarged FIG. 17 show a rotating notches-shaft, containing within the central semiconductor processing-section of the uppertunnelblock in transverse direction multi sharply-profiled aside each other micro-meter high notches on behalf of the removal of the remaining lightning-layer.

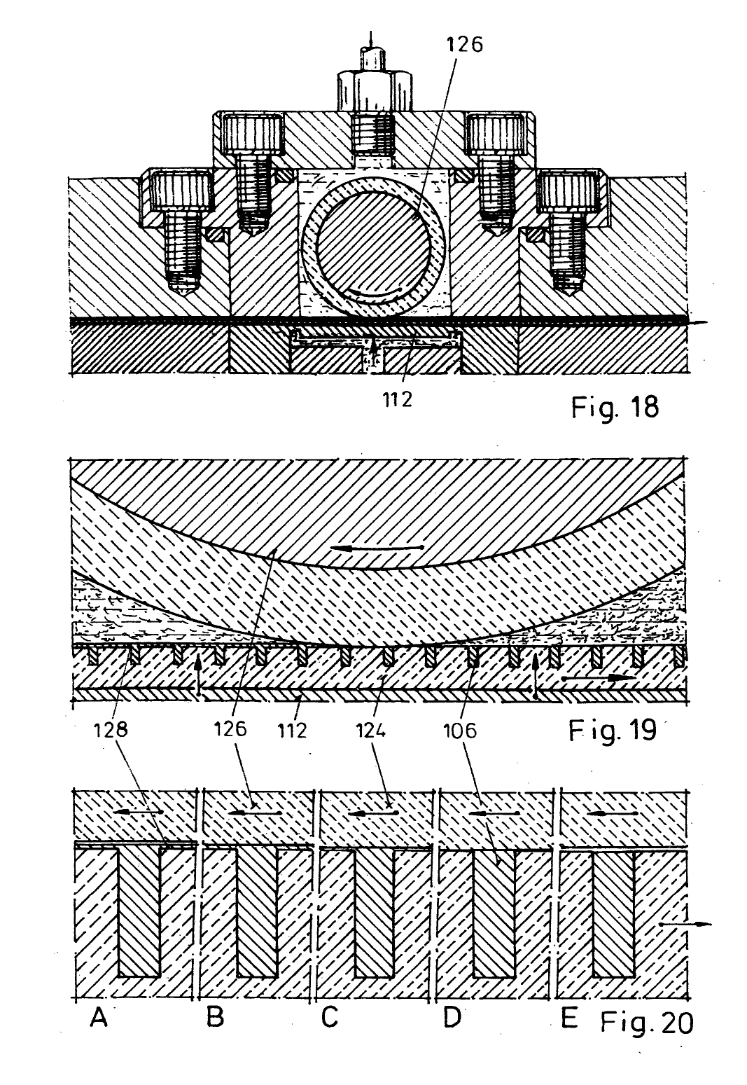

FIG. 18, very enlarged FIG. 19 and strongly enlarged FIGS. 20A through E show after the in a foregoing tunnel-section by means of metallic particles filling these semiconductor crevices and there-upon the taking place of an oven-and cooling-off treatment, thereafter the taking place of removal of at-least the additionally applied typically sub-micrometer high metallic layer.

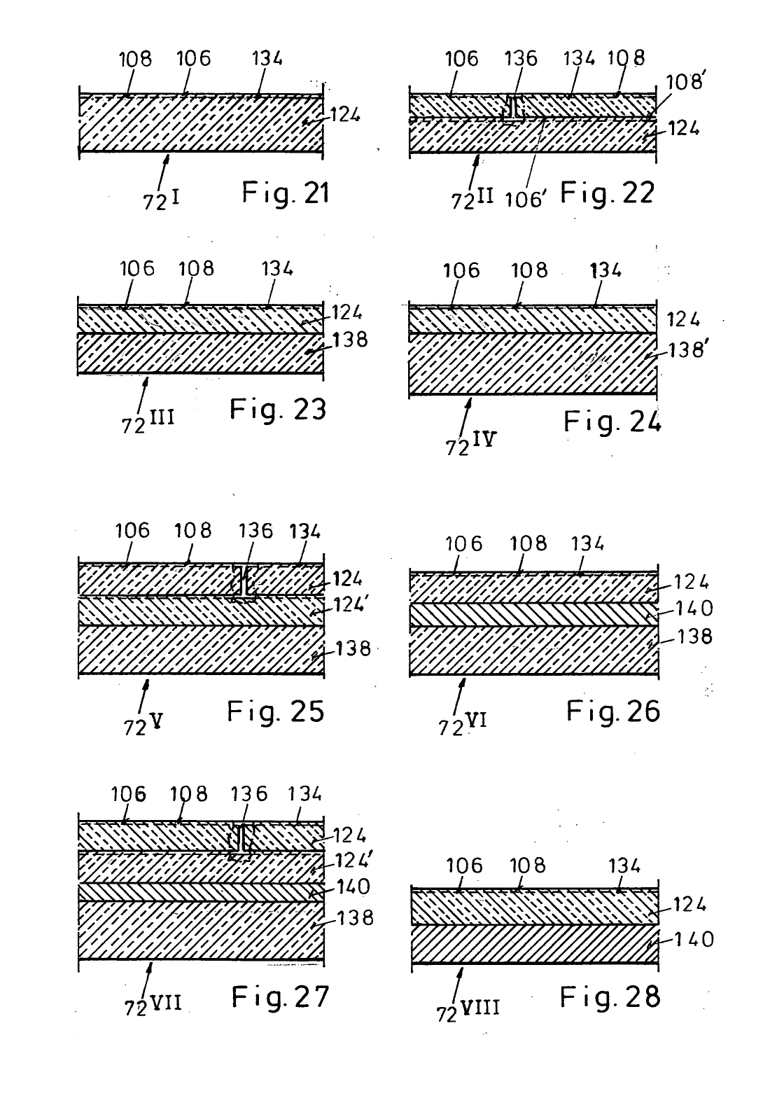

FIG. 21 shows a semiconductor chip with only a single di-electric circuitry-.layer, typically containing nanometer sized semiconductor grooves, filled with a metallic substance, under the accomplishing of an electric circuit with electric connection-sections.

FIG. 22 shows a semiconductor chip with two, above each other positioned di-electrical circuitry-layers, each containing such with metal filled grooves and which by means of at-least almost vertical, with metal filled grooves are connected with each other under the forming of with each other connected electric circuit-sections.

FIG. 23 shows a semiconductor chip with a synthetic, typically teflon, underlayer, with such a thereupon anchoriged di-electric toplayer.

FIG. 24 shows thereby a semiconductor chip with a relatively thick synthetic underlayer, that uninterruptedly has been supplied from a folio-storage-roll near the entrance of the tunnel-arrangement.

FIG. 25 shows a semiconductor chip with a synthetic underlayer and two, above each other located di-electrical circuitry-layers, each containing electrical circuit-layers, containing with each other connected electric circuit-sections.

FIG. 26 shows a semiconductor chip, whereby upon a synthetic underlayer a metallic in-between layer, anchoriged thereupon, with thereupon such di-electric top-layer, anchoriged thereupon.

FIG. 27 shows the semiconductor chip according to FIG. 26, whereby upon this metallic in-between layer two above each-other located di-electric layers, each containing such with metal filled grooves and which layers also electrically are connected with each other.

FIG. 28 shows a semiconductor chip with a metallic underlayer and such a thereupon anchoriged di-electrical circuitry-layer, containing such electrical circuitry-layer.

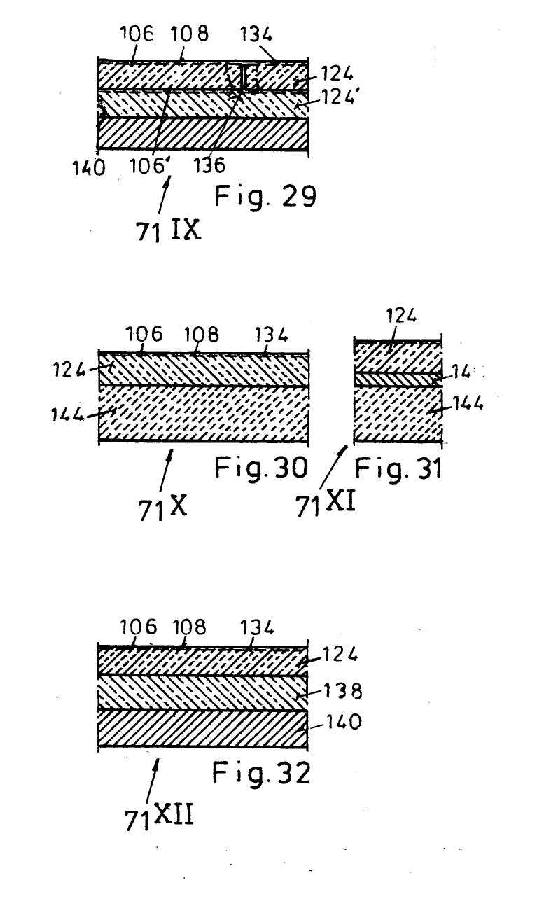

FIG. 29 shows a semiconductor chip with a metallic underlayer and two anchoriged above each-other located di-electrical layers, each also containing such with metal filled semiconductor grooves and which also electrically are connected with each-other.

FIG. 30 shows a semiconductor chip with a paper underlayer and such a thereupon anchoriged di-electrical top-layer.

FIG. 31 shows a semiconductor chip with a paper underlayer, a thereupon anchoriged metallic in-between layer and the thereupon anchoriged di-electrical toplayer.

FIG. 32 shows a semiconductor chip with a metallic underlayer, a synthetic in-between layer and such s toplayer.

The invention shall underneath further be explained on-hand of a number, in the Figures shown execution-examples of the installation-arrangement according to the invention.

FIG. 1 shows schematically the semiconductor installation 10 according to the invention in a side-view thereof.

Such semiconductor installation 10 thereby typically mainly consists of a semiconductor substrate transfer/processing tunnel-arrangement 12, extending in a lineair direction, and containing the uppertunnelblock 14, the undertunnelblock 16 and the in-between positioned central tunnel-passage 18, FIGS. 2 and 3.

In such semiconductor installation near the entrance-side 20 of this semiconductor tunnel-arrangement 12 the location of a storageroll-arrangement 22 on behalf of during its operation the uninterruptedly supply of a very long folio 24, with typically a less than 0.1 mm thickness thereof and containing the typically at-least almost parallel upward sidewall-sections 26 and 28

During the operation of this installation thereby the uninterruptedly taking place of displacement of this folio 24 through this tunnel-passage 18. Thereby in the successive sections of the central upper semiconductor processing-part of this tunnel-passage 18 the uninterruptedly taking place of the establishing of at-least one semiconductor layer upon the top-side of this folio under the accomplishing of successive, uninterruptedly displacing semiconductor substrate-sections underneath the upper processing-section of this tunnel-passage.

FIG. 3 shows a cross-section in the length-direction of the entrance-section of this semiconductor tunnel 12 at its central semiconductor processing-section.

On behalf of the anchorage of the first semiconductor layer upon this folio 24 near the entrance 20 of the tunnel-passage 18 behind the strip-shaped lock-section 30 and such through the strip-shaped supply-section 32 in the upper-tunnelblock 14 at the uppersplit-section of the tunnel-passage 18 the uninterruptedly taking place of the supply of the combination of low-boiling fluidic support-medium 36 and parts of fluidic stitch-medium 38.

Thereby by means of an in the lower section of this uppertunnelblock 14 contained strip-shaped transducer-arrangement 40, functioning also as a heating-source, in the underneath thereof located section of this upper processing-splitsection the taking place of evaporation of this low-boiling fluidic support-medium 36, with thereby deposition of these parts of fluidic stitch-medium 38 upon the successive folio-sections, displacing underneath, under the creation of an uniform micrometer high film of this fluidic stitch-substance 38 and whereby in a following strip-shaped discharge-section 42 in this uppertunnelblock 14 the continuously taking place of discharge of the evaporated medium.

Thereby FIG. 3A strongly enlarged discloses a section of the uppersplit 34 underneath this transducer-arrangement 40, with therein already the taking place of deposition of parts of the fluidic stitch-substance 38 upon the successive underneath thereof folio-sections 24 and whereby FIG. 3B shows a section of this uppersplit 34 behind this discharge-section 42, with thereby at this place such an established micrometer high layer of this stitch-medium 38 upon these successive folio-sections 24, displacing underneath.

Thereby, as is shown in the FIGS. 3 and strongly enlarged FIG. 4, at-least locally in at-least the topwall of the undertunnelblock 16 the location of, as seen in the direction of displacement of these successive uninterruptedly above-thereof displacing semiconductor substrate-sections 44, successive, in the length-direction of this tunnel extending grooves 46, with at the entrance-side thereof the joining thereupon of the strip-shaped supply-section 48 for typically high-boiling fluidic transfer/guidance-medium 50, with at the exit-side thereof the connection thereupon of the strip-shaped discharge-section 54 on behalf of the continuously maintaining of successive flows thereof along the underwall of these successive folio-sections under the thereby simultaneously maintaining of a micrometer high film thereof in at-least also the in-between undersplit-section 58 and supporting the displacement of these successive semiconductor substrate-sections through the tunnel-passage 18.

Thereby, as further is shown in FIG. 4, in the successive sections of the central upper semiconductor processing-section 60 of the tunnel-passage the uninterruptedly building-up of the successive semiconductor layers upon the top-side of this folio under the accomplishing of these successive semiconductor substrate-sections 44, uninterruptedly displacing underneath its central upper processing-splitsection 34.

FIG. 5 shows a schematic sideview of the alternative semiconductor installation 10′, whereby therein during its operation in the device 62 the uninterruptedly taking place of separation of the successive sections of the metallic folio 24′ from the in the semiconductor tunnel-arrangement 12′ established successive semiconductor substrate-sections 44′.

Thereby these successive folio-sections are derived from the folio-storageroll 22′.

On behalf of the establishing of such separation thereby precedingly in the begin-section of the tunnel-arrangement 12′ upon these successive folio-sections the appliance of a micrometer high film high-boiling fluidic medium, typically gallium, upon at-least the central semiconductor processing-section thereof.

Thereby by means of in-addition the roll-establishing 64 the displacing of these successive folio-sections toward the cleaning-device 66 on behalf of the therein uninterruptedly taking place of cleaning in particular its top-surface.

Thereupon thereby in the roll-arrangement 68 the taking place of storage of these successive folio-sections.

Thereby this roll-arrangement 68 also functions on behalf of the thereby therewith exercising a tractive power on these successive folio-sections.

In the adapted device 70 thereby after such cleaning of the successive, therein uninterruptedly supplied semiconductor substrate-sections 44′ the taking place of dividing thereof into semiconductor chips.

The in at-least FIGS. 1, 2 and 5 shown folio 24 typically consists of a synthetic or metallic substance and whereby consequently the semiconductor bottom-layer of the in the tunnel-arrangement 12 of this installation 10 accomplished successive semiconductor substrate-sections 44 and therewith also such semiconductor chip 72 at-least also consists of such synthetic or metallic substance,

FIG. 6 shows the semiconductor installation 10″, whereby near the entrance of the tunnel-arrangement 12″ the roll-arrangement 78 on behalf of the again importation of the in the device 66″ cleaned successive sections of the other folio 24″ into this semiconductor tunnel-arrangement 12″, with its typically functioning as an uninterrupted semiconductor support/transfer-band.

In the device 80 beyond the cleaning-device 66″ thereby the taking place of the building-up of a micrometer high film temporary fluidic stitch-substance 82 upon the successive, uninterruptedly displacing sections of the thereto to a small extent thicker metallic band 76. Thereby in a favourable operation of the installation 10″ the taking place of an uninterrupted supply of successive folio-sections 74 from the folio-storageroll 22″ on behalf of the in the entrance-section 20″ of this tunnel-arrangement 12″ applying thereof upon this band 76, with thereby this in-between positioned micrometer high layer of the temporary stitch-substance 82.

Furthermore, by means of this stitch-substance 76 such an to a sufficient extent temporary anchoraging of the in this tunnel-arrangement 12″ established successive semiconductor substrate-sections 44″ upon the successive band-sections 76, that in the device 62″ behind this tunnel-arrangement the possibly taking place of separation of these semiconductor substrate-sections from the successive band-sections.

FIG. 7 shows a favourable execution of the semiconductor support/transfer-band, whereby its top-wall at the central semiconductor processing-section 60′″ to a small extent is deepened on behalf of the therein building-up of the successive semiconductor substrate-sections 44′″, with typically the successive folio-sections 74 as a definite semiconductor underlayer thereof.

Thereby the successive folio-sections 74 as a definite bottom-layer of such successive semiconductor substrate-sections are to a sufficient extent anchorized upon the deepened central section 84 of this band by means of a mechanic contact of these thereto optimal flat successive folio-sections with the also optimal flat deepened top-wall-sections of this band.

Such in addition by means of thereby the appliance of such semiconductor substrate support/transfer-band 76, that it with at-least one upward sidewall 86 corresponds with a flat upward sidewall 88 of the tunnel-passage 18′″.

Furthermore, that thereby also thereto the upward sidewall 90 of the deepened section 84 of this band 76, that corresponds with the upward sidewall 86 thereof, also to a sufficient extent in both its length- and height-direction is flat and such also for the therewith corresponding upward sidewall 26 of the successive folio-sections 74.

Furthermore, that thereby during the heat-treatments of a toplayer-section of the successive semiconductor substrate-sections 44, as also described in the other PCT Patent-Applications of the applicant, in addition the preventage of an unallowable transformation in transverse direction thereof.

Thereby for that purpose in successive semiconductor heat-treatmentsections, located in the underwall of the uppertunnelblock 14 the insertion of a strip-shaped micrometer wide electric heating-element, extending in transverse direction, with thereby during a very short period of time the heating of only a (sub) micrometer height of the applied semiconductor substance, as for instance a di-electric substance, with typically in the length-direction thereafter a strip-shaped cooling-off section in this block.

Furthermore, also thereto in a favourable method in this tunnel-arrangement 12 building-up of typically only one semiconductor top-layer upon typically the synthetic folio 24, through which at-least also the following:
a) a small acceptable transformation thereof during such heating-process; and
b) a small acceptable expansion thereof in the length-direction of the tunnel-passage 18 during the lineair displacement thereof therethrough, because thereby in a strip-shaped tunnel-section typically only one semiconductor lightning process is required.

Thereby during the operation of this tunnel-arrangement with the uninterrupted displacement of such combination of the uninterrupted band 76 and typically uninterrupted successive semiconductor substrate-sections 44, the in addition thereby maintaining of an almost parallel position of such upward sidewall of this folio 24 with the therewith corresponding upward sidewall 88 of the tunnel-passage 18 by means of successive flows of gaseous medium along the top-wall thereof and the thereby maintaining of the following:
a) a guidance of the band 76 along such upward sidewall of the tunnel-passage 18; and
b) reclination of the upward sidewall 92 of the successive folio-sections 74 against the upward sidewall 90 of the deepened topwall-section 84 of this band 76.

FIG. 8 shows for the semiconductor installation 10 means on behalf of during its operation the establishing therein within the entrance-section 20 of the therein located semiconductor tunnel-arrangement 12 the joining of the back-side 94 of the already displacing folio 24 therethrough with the front-side 96 of the following folio 24.

For that purpose these folios 24 contain at their front-side the upward sidewall 96 and at their back-side the upward sidewall 98, both being upmost flat and at-least almost parallel with each other.

In a favourable execution of such folio 24, stored in the storage-roll 68, thereby its length is greater then that of this tunnel-arrangement 12, typically more than 20 meter and even possibly 5000 meter on behalf of during approx. 2 months the maintaining of a continuous uninterruptedly displacement thereof therethrough and with a therein simultaneously uninterruptedly taking place of the successive semiconductor processings.

Such under a speed of displacement of this folio of typically 2 mm/second.

In that way, at least an approx. 3 hours time-limit, before a following folio has to be brought in.

Thereby the tunnel-entrancesection 20″ in a favourable execution of its top-side the open central section 100 on behalf of inspection of such accomplished critical joining of these successive folios, and whereby by means of a transverse-end 88 of the tunnel-passage 18 the taking place of a guidance of the following folio, brought-in.

Thereby typically at-least in addition by means of successive flows of gaseous medium along this new folio in the direction of the foregoing folio, with the maintaining of a higher velocity of the front-section of this folio then that of the foregoing folio, until such joining has taken place.

The combination of the cleaning-device 60″ and the thereafter located device 80 contain thereby such means, that therein also the taking place of removal of an eventually, upon the applied band 24″ deposited substance, as is shown in FIG. 6.

Such possible single semiconductor top-layer instead of a number of above each other positioned semiconductor layers, with vertical metallic connections in-between, as until now commonly is used in the existing semiconductor industry under the appliance of almost cilindrical semiconductor wafers and at-least also individual semiconductor processing-modules.

In an alternative, possible execution of such folio 24 is its length less than that of the tunnel-arrangement 12, through which a thereby required often introducing of another folio, typically within 2 hours.

By means of such joining of the following folio with the foregoing folio in the entrance-section of the tunnel-arrangement thereby in that way possibly the taking place of at-least also an uninterrupted supply and discharge of semiconductor processing-medium toward and from the successive strip-shaped upper semiconductor processing-splitsections of this tunnel-arrangement.

In that way an entirely new semiconductor transfer/process processing technology under the establishing of a new generation of semiconductor chips, with thereby the appliance of any possible substance for such folio or a combination of substances for it, as also is shown and described in the other, simultaneously applied PCT Patent-Applications.

In FIG. 9 still a partly top-view is shown of the successive semiconductor substrate-sections 44, uninterruptedly displacing through the device 62 behind the tunnel-exit 52, FIG. 1.

Thereby such semiconductor substrate-section 44 consists of a number of successive, in transverse direction aside each other positioned semiconductor substrate-sections, from which by means of separation thereof in this device the establishing of semiconductor chips 72, typically containing only a single semiconductor top-layer upon the typically synthetic folio 24 ,as a definite semiconductor bottom-layer thereof.

FIG. 10 shows very enlarged a top-view of the accomplished chip 72, containing upon this typically synthetic bottom-layer the semiconductor top-layer 102 in a stitch-together condition as a replacement for the existing semiconductor chips with a number of above each-other positioned semiconductor layers, with in-between metallic semiconductor connections.

Thereby typically the size of such semiconductor chip 72 in cross-direction is approx. the same as its size in the length-direction.

Furthermore for such semiconductor chip any possible number of electric connections 134 and any possible position thereof.

Furthermore, for the semiconductor bottom-layer of such chip any possible combination of above each-other positioned micrometer high layers, as for instance a di-electric bottom-layer, a metallic in-between layer and a di-electric top-layer.

Furthermore contains this semiconductor installation such means, that thereby by means of a strip-shaped lightningpattern applying-device, located in the upper-tunnelblock of the therein located semiconductor tunnel-arrangement, the successively taking place of applying a strip-shaped lightning-pattern upon the successive, underneath thereof displacing semiconductor substrate-sections.

Thereby for that purpose in both transverse-ends of such semiconductor band or—folio the applied mini recesses 104, FIG. 8, on behalf of during the lightning-process by means of this band or folio therewith displacing this lightning-device together with the applied successive semiconductor substrate-sections.

As by means of in such tunnel-arrangement possibly the accomplishing of only a single semiconductor layer, also functioning as a semiconductor top-layer of the successive, uninterruptedly therethrough displacing semiconductor substrate-sections, at least the following semiconductor layer-structures of there-out accomplished semiconductor chips:
a) the combination of a synthetic bottom-layer and a di-electric top-layer; or
b) the combination of a synthetic bottom-layer, a metallic in-between layer and a di-electric top-layer; or
c) the combination of a metallic bottom-layer and a di-electric top-layer; or
d) only a di-electric top-layer; or
e) the combination of a di-electric bottom-layer, metallic in-between layer and a di-electric top-layer.

If however in such tunnel-arrangement the accomplishing of a number of above each other positioned primary semiconductor layers with secondary in-between layers, containing a number of metallic connections between these primary semiconductor layers, thereby also the possibly building-up of the under a) through e) described semiconductor layer-structures of such, from that accomplished semiconductor chips.

If in such semiconductor tunnel-arrangement exclusively the appliance of an uninterrupted metallic semiconductor substrate support/transfer-band 76, with the roll-arrangements 64 and 78 nearest the exit and entrance thereof, FIG. 6, and with therein the accomplishing of successive semiconductor substrate-sections with only a single semiconductor layer, thereby also functioning as a semiconductor top-layer thereof, thereby however only the semiconductor layer-structures of the in such device behind the tunnel-exit accomplished semiconductor chips, as noted under d) and e).

As thereby in such tunnel-arrangement the accomplishing of successive semiconductor substrate-sections, containing a number of above each-other located primary semiconductor layers with secondary semiconductor in-between layers, wherein the appliance of a number of metallic connections between these primary layers, thereby also for the in such device obtained semiconductor chips only these under d) and e) noted semiconductor layer-structures.

If however the appliance of the combination of such uninterrupted semiconductor substrate support/transfer-band, with the thereupon uninterruptedly from a storage-roll supplied successive semiconductor folio-sections, thereby again at-least the under a) through e) noted possible semiconductor layer-structures of the therefrom accomplished semiconductor chips.

Such semiconductor synthetic folio or—layer contains a sufficient high melting-temperature and di-electric value thereof on behalf of the functioning thereof as an at-least semiconductor bottom-layer of the successive, in this tunnel-arrangement accomplished semiconductor substrate-sections and thereupon in a thereafter located device at-least also by means of dividing thereof the accomplishing of semiconductor chips with such semiconductor bottom-layer thereof.

Furthermore, at least also a paper folio in a for that purpose suitable execution and composition thereof is also applicable for at-least such semiconductor bottom-layer of the successive, in this tunnel-arrangement establised semiconductor substrate-sections and in the there-upon located device by means of dividing the establishing of successive semiconductor chips.

Furthermore, also any possible size of such typically rectangular semiconductor chip, with such at-least also paper bottom-layer in both its length- and transverse direction.

In a favourable execution of such synthetic- or paper folio in a device , whether or not contained in this semiconductor installation, upon at-least its central semiconductor processing-section the taking place of deposition of a micrometer high layer of a di-electric substance on behalf of in its tunnel-arrangement the accomplishing of with a metallic substance filled nanometer sized crevices in the top-layer of the therein established successive semiconductor substrate-sections and subsequently by means of at-least also dividing thereof in the thereafter located device the obtaining of semiconductor chips with such semiconductor bottom- and top-layer thereof.

Furthermore, in this tunnel-arrangement by means of successive folio/band-sections in combination with successive flows of a lock-medium in both transverse ends of the tunnel-passage a medium-lock to prevent the escape of processing-medium from the primary uppersplit into the secondary bottomsplit and medium from the bottomspiit into the uppersplit.

After the in the semiconductor tunnel-arrangement accomplished typically nanometer wide crevices in the upper topography 108 of the di-electric toplayer of the successive semiconductor substrate-sections 44 by means of also the preceding lightning-process of the semiconductor tip-layer 110, in successive strip-shaped upper processing-splitsections 34 the continuously taking place of successive phases of a total cleaning-process of these crevices 106, as shown in FIGS. 11A through F.

Thereby the appliance of the strip-shaped thrust-wall 112 as part of the upperwall of the lowertunnelblck 16, whereby by means of the rotating notches-shaft 114 , located in an strip-shaped compartment of this block, typically a high-frequently vibrating action thereof is maintained and such underneath these successive semiconductor substrate-sections 44, under also the continuously maintaining of a vibrating action thereof, as is shown in FIG. 12.

Thereby in the FIGS. 11A and B in successive split-sections by means of typically fluidic cleaning medium 116 the taking place of the start-phase of this cleaning-process.

Thereby successively an upward compression-stroke, with the storage therein of this cleaning-medium, and in the thereupon following downward expansion-stroke the stowing of the combination of parts of this fluidic cleaning-medium in combination with the particles of typically di-electric substance 118 and parts of the etch-medium 120, still present therein, until such cleaning-process has taken place, FIGS. 11C and D.

Subsequently, in typically a number of thereupon following uppersplit-sections 34 by means of gaseous medium 122, typically N2, the removal of this fluidic medium out of these grooves 106, FIGS. 11E and F.

Subsequently, in a following strip-shaped tunnel-section, FIG. 13, the uninterruptedly taking place by means of a grinding-process the removal of the upon the di-electric toplayer 124 supplied remaining hard di-electric toplayer 110.

Such by means of an in the uppertunnelblock 14 located rotating grinding-shaft 126 and whereby such grinding-process stringly enlarged is shown in FIG. 14 and very strongly enlarged in FIGS. 15A through E. Thereby by means of the strip-shaped thrust-wall 112 in the lowertunnelblock 16 an upward thrust-force of the successive semiconductor substrate-sections 44 against this grinding-shaft.

Such removal of the hard di-electric layer 110 is also possible by means of the rotating notches-shaft 130, containing a very large number of micrometer-high sharply profiled notches 132, as is shown in FIGS. 16 and 17.

After the appliance of the combination of low-boiling fluidic support-medium 36 and metallic parts 134 and thereby at-least also the filling therewith of the crevices 106, under the in addition building-up of a micrometer high layer thereof upon the topwall of the successive, underneath displacing semiconductor substrate-sections 44, with the appliance of an upper transducer-arrangement 40 in the uppertunnelblock 14, FIG. 3, on behalf of in-addition the evaporation of the fluidic support-medium,

Thereby the thereupon following oven-treatment of the supplied layer by means of a typically micrometer wide electric heating-element, located in the uppertunnelblock 14, with a thereupon following cooling-off process of this applied layer.

Thereupon in a following tunnel-section typically by means of such rotary grinding-shaft 126 the taking place of removal of at-least the excessively supplied metallic substance under the establishing of a (sub) micrometer high metallic layer 128.

Such grinding system for this metal-layer is shown in the FIGS. 18 and 19 and very enlarged in the FIGS. 20A through E.

As an alternative the possibly at-first in a tunnel-section filling of these crevices in the combination of the di-electric toplayer and the micrometer high hard di-electric toplayer with metal and thereupon in the following tunnel-section by means of such rotating grinding-shaft the removal of the combination of this hard di-electric lightning layer and the thereupon applied micrometer high metallic layer.

FIG. 21 shows a semiconductor chip 721, accomplished in the device 70, FIG. 5, or the device 62, FIG. 1, behind such semiconductor tunnel-arrangement 12, by means of dividing the therein uninterruptedly supplied successive semiconductor substrate-sections 44. This chip is executed such, that it contains only one electric circuitry-layer 124, and whereby its top-topography 108 contains multi, with a metallic substance filled, typically nanometer wide semiconductor crevices 106, connected with each-other, under the accomplishing of an electric circuit, with thereupon a number of electric connections 134.

FIG. 22 shows the semiconductor chip 72II, whereby it contains two, above each other located and with each other anchorized di-electric layers 124 and 124′, each containing electric circuits, connected with each other.

Thereby in the top-topography 108 and 108′ of each layer also the insertion of such multi, with a metallic substance filled, typically nanometer-wide crevices 106 and 106′, wherein an accomplished electric circuit-section, and whereby these crevices locally with at-least almost vertical connection-crevices 136 are inner-connected, and the top-circuit contains a number of electric connections 134.

FIG. 23 shows the semiconductor chip 72III, whereby it consists of an at-least to a sufficient extent heat-resistant synthetic, typically teflon, bottomlayer 138, with thereupon such an in this tunnel-arrangement builded-up and therewith whether or not with a (sub) micrometer high in-between layer stitch-substance anchored di-electric toplayer 124, containing again in its top-topography 108 the with metal filled crevices 106, with thereupon the electric connections 134.

FIG. 24 shows the semiconductor chip 72IV, whereby it consists of a relatively thick synthetic folio 38′, typically uninterruptedly supplied from a folio storage-roll toward the entrance of the tunnel-arrangement, FIG. 1 or 5, or for that purpose use has been made of an uninterrupted semiconductor substrate support/transfer-band, with a roll-arrangement near its entrance and exit, FIG. 6.

FIG. 25 shows the semiconductor chip 72V, whereby it consists of such synthetic bottomlayer 138, with there-upon such two, in this tunnel-arrangement builded-up upon eachother di-electric circuit-layers 124 and 124′, containing also such a with metal filled crevices 106.

FIG. 26 shows the semiconductor chip 72VI, whereby upon the synthetic bottomlayer 138 a thereupon also anchored metallic in-between layer 140, with thereupon anchored the di-electric circuit-layer 124,

FIG. 27 shows the semiconductor chip 72VII, whereby upon this combination of synthetic bottom-layer 138 and metallic in-between layer 140 two thereupon above each-other located circuit-layers 124 and 124′, with also the with metal filled connection-crevices 136 between the with metal filled crevices 106 and 106′ in the top-topography of both layers.

FIG. 28 shows the semiconductor chip 72VIII, with the metallic bottomlayer 140 and such a thereupon anchored circuit-layer 124, containing also the with metal filled crevices 106 in the top-topography 108 thereof and with thereupon some electric connections 134.

FIG. 29 shows the semiconductor chip 72IX, with a metallic bottomlayer 140 and two thereupon anchored above each-other positioned di-electric circuit-layers 124 and 124′, each also containing such a with metal filled crevices 106 and 106′ and the connection-crevices 136.

FIG. 30 shows the semiconductor chip 72X, with a paper bottomlayer 144 and such a thereupon anchored di-electric circuit-layer 124, with in the top-topography 108 thereof again the location of the with metal filled crevices 106 and the thereupon connected electric connections 134.

FIG. 31 shows the semiconductor chip 72XI, with a paper bottomlayer 144 and the thereupon anchored metallic in-between layer 144 and the thereupon anchored di-electric circuit-layer 124.

FIG. 32 shows the semiconductor chip 72XII, with a metallic bottomlayer 140, a thereupon anchored synthetic layer 138 and thereupon such di-electric circuit-layer 124.

Furthermore, in addition and within the scope of the invention the typically possible application of the semiconductor devices and—methods, as described in the Claims.

1-124. (canceled)

125. A semiconductor chip, whereby at-least the end-phase of construction thereof has taken place in at-least a semiconductor installation, extending in its length-direction.

126. The semiconductor chip according to claim 125, and whereby it has been accomplished in a device thereof out of, as seen in the length-direction of this installation, successive, at-least also therein established semiconductor substrate-sections.

127. The semiconductor chip according to claim 125, and whereby therein in this semiconductor installation the location of a semiconductor substrate transfer/processing tunnel arrangement.

128. The semiconductor chip according to claim 127, and whereby during the operation of this installation in this tunnel-arrangement the at-least almost continuously taking place of an uniform linear displacement of these successive substrate-sections therethrough from at-least almost its entrance-side toward its exit-side.

129. The semiconductor chip according to claim 127, further characterized such, that thereby at-least also for such successive substrate-sections the usage is made of during the operation of this tunnel-arrangement the typically almost uninterruptedly taking place of displacement there through of via its entrance supplied folio-sections with a small thickness thereof as an at-least temporary semiconductor bottom-layer thereof.

130. The semiconductor chip according to claim 129, further characterized such that thereby for that purpose this installation near the entrance of the therein located tunnel-arrangement contains a folio-storageroll, wherein the storage of such very long folio with a thickness of typically less than 0.1 mm.

131. The semiconductor chip according to claim 130, further characterized such, that as thereby the successive substrate-sections in the exit-section of this tunnel-arrangement contains a folio-storageroll, wherein the storage of such very long folio with a thickness of typically less than 0.1 mm.

132. The semiconductor chip according to claim 131, wherein only after the being accomplished of a number of such upon each-other located si-electric layers under the appliance of the combination of such strip-shaped medium supply-section, a vibrating evaporation-device and a medium discharge-section, the also had taken place of such combination of an oven processing under having established a fluidic layer of this di-electric substance and the thereupon followed cooling-off process, under the having accomplished of a solid condition of such semiconductor layer.

133. The semiconductor chip according to claim 131, wherein at least also such micrometer-high di-electric layer thereof had been accomplished in this strip-shaped tunnel-arrangement by means of the in its uppertunnelblock located strip-shaped medium supply-section the uninterruptedly having taken place of the supply of the combination of low-boiling fluidic support-medium and nanometer-sized particles of a dielectric substance, and by means of a thereupon followed strip-shaped vibrating heating-device, typically a transducer-arrangement, therewith at-least in addition underneath its begin-section the gradually having taken place of a continuously further evaporation of this low-boiling fluidic medium, with the simultaneously having taken place of discharge of this evaporated medium in a thereupon following strip-shaped discharge-section under the having taken place of a to a sufficient extent uniform deposition of these particles upon the successive, uninterruptedly underneath thereof having displaced semiconductor substrate-sections, under the having accomplished such a typically micrometer-high layer of particles of this di-electric substance.

134. The semiconductor chip according to claim 133, wherein the tunnel-arrangement has been executed such, that thereby by means of this developed vaporized medium in combination with this vibrating strip-shaped heating-device as also a vibrating thrust-wall, the maintaining had taken place of a contact-free condition of such applied layer of a di-electric substance with the uppertunnelblock-section, located there-above, and such also in these thereupon followed strip-shaped oven- and cooling-off sections.

135. The semiconductor chip according to claim 134, wherein in a thereupon following section of this tunnel-arrangement upon such a di-electric top-layer a micrometer-high lightning-layer had been applied, and in thereupon following tunnel-sections the therein had been established multi, with a metallic substance filled typically nanometer-wide crevices as part of a semiconductor electric circuit-layer with electric connection-sections thereof.

136. The semiconductor chip according to claim 135, wherein for that purpose in this tunnel-arrangement the uninterruptedly establishing had taken place of successive substrate-sections, containing at-least nanometer-wide, with a metal filled semiconductor crevices in the di-electric toplayer thereof and electric connections therefor, thereby in a device, located behind the exit of this tunnel-arrangement, by means of the uninterruptedly had taken place of dividing the therein uninterruptedly supplied successive substrate-sections in both their length- and transverse direction, in both their length- and transverse direction, the accomplishment had been made of successive, in transverse direction aside each other located clusters of semiconductor chips at the exit-side of such device.

137. The semiconductor chip according to claim 136, wherein it contains only one di-electric total-layer, and whereby in its top-section the insertion of many, with a metallic sub stance filled typically nanometer-wide crevices, connected with each other, under the establishing of an electric circuit, containing electric connection-sections.

138. The semiconductor chip according to claim 137, wherein it contains a number of above each-other located di-electric layers, whereby in the upper-topography of such layer the location of multi, with a metallic substance filled typically nanometer-wide crevices, connected with each other, under the obtaining of an electric circuit, with the electric circuits in these layers by means of at-least almost vertical connection-crevices are connected with each-other, and the upper electric circuit contains electric connection-sections,

139. The semiconductor chip according to claim 125, wherein at-least also the use of at-least some of the semiconductor means, that are shown and described in the by the Applicant applied US Patent-applications with regard to such semiconductor tunnel-arrangement.

140. A method for manufacturing a semiconductor chip, wherein at-least the end-phase of construction thereof has taken place in at-least a semiconductor installation, extending in its length-direction.

141. A method to accomplish a semiconductor chip according to claim 140, wherein such chip has been accomplished in a device thereof out of, as seen in the length-direction of this installation, successive, at-least also therein established semiconductor substrate-sections.

142. A method to accomplish a semiconductor chip according to claim 140, wherein thereto in this installation the location of a semiconductor substrate transfer/processing tunnel-arrangement.

143. A method to accomplish a semiconductor chip according to claim 142, and wherein the successive substrate-sections in the exit-section of this tunnel-arrangement containing at least also nanometer-wide, with metal filled crevices in at-least the di-electric top-layer thereof.

144. A method to accomplish a semiconductor chip according to claim 140, wherein for the di-electric top-layer of these successive substrate-sections by means of a scraping-off process the had been accomplished of such a to a sufficient extent flatness thereof, in a thereupon followed section of this tunnel-arrangement a thereupon micrometer-high lightning-layer had been applied, and in thereupon following tunnel-sections the therein had been established of multi, with a metallic substance filled typically nanometer-wide crevices in the di-electric top-layer, and thereupon therein the having established of a semiconductor electric circuit-layer with electric connection-sections.

145. A method to accomplish a semiconductor chip according to claim 144, wherein for that purpose in this tunnel-arrangement the uninterruptedly establishing had taken place of successive substrate-sections, containing at-least nanometer-wide, with each-other located clusters of semiconductor chips at the exit-side of such device.

146. A method to accomplish a semiconductor chip according to claim 144, wherein it contains only one di-electric total-layer, and whereby in this top-section the insertion of many, with a metallic substance filled typically nanometer-wide crevices, connected with each-other, under the establishing of a electric circuit, containing electric connectionsection-sections.

147. A method to accomplish a semiconductor chip according to claim 146, and whereby it consists of a to an at-least sufficient extent heat-resistant synthetic bottom layer, and in this tunnel-arrangement a whether or not by means of a thereupon applied sub-micrometer-high in between layer of a stitch-substance, and thereupon di-electric layer, containing at-least such with a metallic substance filled nanometer-wide crevices in its top-section.

148. A method to accomplish a semiconductor chip according to claim 147, wherein such di-electric layer already its dielectric top-layer is.

149. A method to accomplish a semiconductor chip according to claim 147, wherein in a strip-shaped section of this tunnel-arrangement upon this folio the having established a micrometer-high layer of a fluidic stitch-substance upon such synthetic bottomlayer.

150. A method to accomplish a semiconductor chip according to claim 146, wherein it exists of at-least a metallic bottom layer and whereby in this tunnel-arrangement the having taken place of a thereupon supplied and therewith whether or not with a (sub) micrometer-high in-between layer of a stitch substance thereupon anchored di-electric layer, containing at-least such with a metallic substance filled semiconductor crevices in its top-section and whereby such di-electric layer typically the di-electric toplayer is.

151. A method to accomplish a semiconductor chip according to claim 150, wherein for these established semiconductor layers the having used of any suitable semiconductor substance on behalf of having been used as typically nanometer-sized semiconductor particles thereof and such typically in combination with fluidic support-medium and under the having taken place of an uninterrupted supply thereof.
